(19) United States
(12) Patent Application Publication
(10) Pub. No.: US 2026/0150534 A1
(43) Pub. Date: May 28, 2026

(54) DISPLAY DEVICE, METHOD OF MANUFACTURING DISPLAY DEVICE, AND ELECTRONIC DEVICE

(71) Applicant: Samsung Display Co., LTD., Yongin-si (KR)

(72) Inventor: MYUNG-WOOK CHOI, Yongin-si (KR)

(21) Appl. No.: 19/228,051

(22) Filed: Jun. 4, 2025

(30) Foreign Application Priority Data
Nov. 27, 2024 (KR) 10-2024-0171839

(51) Int. Cl. H10K 59/131; H10K 59/12

(52) U.S. Cl. CPC H10K 59/131; H10K 59/1201

(57) ABSTRACT

A display device includes a substrate, a first driving voltage supply line in a non-display area, a second driving voltage supply line between the display area and the first driving voltage supply line and spaced apart from the first driving voltage supply line, a bridge electrode electrically connecting the first and second driving voltage supply lines, an organic insulating layer on the bridge electrode and including a first portion adjacent to the first driving voltage supply line and a second portion adjacent to the second driving voltage supply line, and an emission layer in the display area and extending to the non-display area such that one end portion of the emission layer in the non-display area overlaps the bridge electrode. An average thickness of the first portion of the organic insulating layer is less than an average thickness of the second portion of the organic insulating layer.

This application claims priority to Korean Patent Application No. 10-2024-0171839, filed on Nov. 27, 2024, and all the benefits accruing therefrom under 35 U.S.C. § 119, the content of which in its entirety is herein incorporated by reference.

### BACKGROUND

### 1. Field

Embodiments relate to a display device, a method of manufacturing a display device, and an electronic device. More particularly, embodiments relate to a display device including a demultiplexer circuit, a method of manufacturing the display device, and an electronic device including the display device.

### 2. Description of the Related Art

As information technology develops, the importance of display devices providing a connection medium between users and information is being highlighted. For example, the use of display devices, such as a liquid crystal display device (LCD), an organic light emitting display device (OLED), a plasma display device (PDP), or the like is increasing.

The display device includes a display panel for displaying an image and a driver for controlling the image displayed on the display panel. The display panel includes data lines, scan lines, and pixels. The driver includes a data driver for providing data signals to the data lines, a scan driver for providing scan signals to the scan lines, and a driving controller for controlling the data driver and the scan driver. The display device may include a demultiplexer for time-dividing the data signals provided from the data driver.

### SUMMARY

Embodiments provide a display device with improved reliability.

Embodiments also provide a method of manufacturing a display device with improved reliability.

Embodiments also provide an electronic device with improved reliability.

Additional features of the invention will be set forth in the description which follows, and in part will be apparent from the description, or may be learned by practice of the invention.

A display device according to an embodiment includes a substrate including a display area and a non-display area, a first driving voltage supply line disposed in the non-display area, extending in a first direction, and to which a driving voltage is applied, a second driving voltage supply line disposed between the display area and the first driving voltage supply line in a plan view, extending in the first direction, and spaced apart from the first driving voltage supply line, a bridge electrode disposed on the first driving voltage supply line and the second driving voltage supply line, and electrically connecting the first driving voltage supply line and the second driving voltage supply line to each other, an organic insulating layer disposed on the bridge electrode, and including a first portion adjacent to the first driving voltage supply line and a second portion adjacent to the second driving voltage supply line, and an emission layer disposed in the display area and extending from the display area to the non-display area such that one end portion of the emission layer in the non-display area overlaps the bridge electrode in a plan view. An average thickness of the first portion of the organic insulating layer is less than an average thickness of the second portion of the organic insulating layer.

In an embodiment, in a plan view, the first portion of the organic insulating layer may overlap the bridge electrode and may not overlap the emission layer, and the second portion of the organic insulating layer may overlap both the bridge electrode and the emission layer.

In an embodiment, a thickness deviation in the first portion of the organic insulating layer may be greater than a thickness deviation in the second portion of the organic insulating layer.

In an embodiment, in a plan view, the second driving voltage supply line may be spaced apart from the display area in a second direction crossing the first direction, and the first driving voltage supply line may be spaced apart from the second driving voltage supply line in the second direction.

In an embodiment, the first portion of the organic insulating layer may be located in the second direction from the second portion of the organic insulating layer.

In an embodiment, the bridge electrode may define a plurality of holes located between the first driving voltage supply line and the second driving voltage supply line and spaced apart from each other in a plan view.

In an embodiment, the plurality of holes may include first holes adjacent to the first driving voltage supply line, arranged along the first direction, and spaced apart from the emission layer in a plan view. A first-first portion in the first portion of the organic insulating layer, overlapping one of the first holes in a plan view, may have a first thickness. A first-second portion in the first portion of the organic insulating layer, overlapping a first portion of the bridge electrode between the first holes in the first direction in a plan view, may have a second thickness less than the first thickness.

In an embodiment, the plurality of holes may include second holes adjacent to the second driving voltage supply line, arranged along the first direction, and overlapping the emission layer in a plan view A second-first portion in the second portion of the organic insulating layer, overlapping the second holes in a plan view, may have the first thickness. A second-second portion in the second portion of the organic insulating layer, overlapping a second portion of the bridge electrode between the second holes in the first direction in a plan view, may have the first thickness.

In an embodiment, the display device may further include a demultiplexer circuit disposed between the substrate and the bridge electrode and overlapping the bridge electrode in a plan view.

In an embodiment, the display device may further include a pixel electrode disposed in the display area. The bridge electrode may include a same material as the pixel electrode.

A method of manufacturing a display device according to an embodiment includes forming a first driving voltage supply line and a second driving voltage supply line in a non-display area on a substrate including a display area and the non-display area, forming a bridge electrode on the first driving voltage supply line and the second driving voltage supply line, forming a preliminary organic insulating layer on the bridge electrode, patterning the preliminary organic insulating layer using a mask to form an organic insulating layer including a first portion adjacent to the first driving voltage supply line and a second portion adjacent to the second driving voltage supply line, and forming an emission layer extending from the display area to the non-display area such that one end portion of the emission layer in the non-display area overlaps the bridge electrode in a plan view. The first driving voltage supply line extends in a first direction. A driving voltage is applied to the first driving voltage supply line. The second driving voltage supply line is disposed between the display area and the first driving voltage supply line in a plan view, extends in the first direction, and is spaced apart from the first driving voltage supply line. The bridge electrode electrically connects the first driving voltage supply line and the second driving voltage supply line. An average thickness of the first portion of the organic insulating layer is less than an average thickness of the second portion of the organic insulating layer.

In an embodiment, in a plan view, the first portion of the organic insulating layer may overlap the bridge electrode and not overlap the emission layer, and the second portion of the organic insulating layer may overlap both the bridge electrode and the emission layer.

In an embodiment, a thickness deviation in the first portion of the organic insulating layer may be greater than a thickness deviation in the second portion of the organic insulating layer.

In an embodiment, the mask may be a halftone mask.

In an embodiment, the bridge electrode may define a plurality of holes located between the first driving voltage supply line and the second driving voltage supply line and spaced apart from each other in a plan view.

In an embodiment, the plurality of holes may include first holes adjacent to the first driving voltage supply line, arranged along the first direction, and spaced apart from the emission layer in a plan view. A first-first portion in the first portion of the organic insulating layer, overlapping the first holes in a plan view, may have a first thickness. A first-second portion in the first portion of the organic insulating layer, overlapping a first portion of the bridge electrode between the first holes in the first direction in a plan view, may have a second thickness less than the first thickness.

In an embodiment, the plurality of holes may include second holes adjacent to the second driving voltage supply line, arranged along the first direction, and overlapping the emission layer in a plan view. A second-first portion in the second portion of the organic insulating layer, overlapping the second holes in a plan view, may have the first thickness. A second-second portion in the second portion of the organic insulating layer, overlapping a second portion of the bridge electrode between the second holes in the first direction in a plan view, may have the first thickness.

In an embodiment, the method may further include, before the forming of the first driving voltage supply line and the second driving voltage supply line, forming a pixel circuit in the display area and a demultiplexer circuit in the non-display area. The bridge electrode may overlap the demultiplexer circuit in a plan view.

In an embodiment, the forming of the bridge electrode may include forming a conductive layer on the display area and the non-display area, and patterning the conductive layer to form a pixel electrode in the display area and the bridge electrode in the non-display area.

An electronic device according to an embodiment includes a window, a housing coupled with the window to provide an internal space, and a display device accommodated in the internal space between the housing and the window. The display device includes a substrate including a display area and a non-display area, a first driving voltage supply line disposed in the non-display area, extending in a first direction, and to which a driving voltage is applied, a second driving voltage supply line disposed between the display area and the first driving voltage supply line in a plan view, extending in the first direction, and spaced apart from the first driving voltage supply line, a bridge electrode disposed on the first driving voltage supply line and the second driving voltage supply line, and electrically connecting the first driving voltage supply line and the second driving voltage supply line to each other, an organic insulating layer disposed on the bridge electrode, and including a first portion adjacent to the first driving voltage supply line and a second portion adjacent to the second driving voltage supply line, and an emission layer disposed in the display area and extending from the display area to the non-display area such that one end portion of the emission layer in the non-display area overlaps the bridge electrode in a plan view. An average thickness of the first portion of the organic insulating layer is less than an average thickness of the second portion of the organic insulating layer.

A display device according to embodiments may include a bridge electrode electrically connecting driving voltage supply lines which are spaced apart from each other in a non-display area. It is possible to prevent or reduce an abnormal light emission in which an emission layer emits light on the bridge electrode in the non-display area, thereby improving a reliability of the display device may be effectively improved.

It is to be understood that both the foregoing general description and the following detailed description are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this specification, illustrate embodiments of the invention, and together with the description serve to explain the invention.

FIG. 1 is a block diagram illustrating a display device according to an embodiment.

FIG. 2 is a plan view illustrating a display device according to an embodiment.

FIG. 3 is a schematic diagram of an equivalent circuit of a pixel according to an embodiment.

FIG. 4 is a cross-sectional view illustrating a display device according to an embodiment.

FIG. 5 is a schematic diagram of an equivalent circuit of a demultiplexer according to an embodiment.

FIG. 6 and FIG. 7 are enlarged plan views illustrating an example of an area A of FIG. 2.

FIG. 8 is a cross-sectional view taken along line I-I′ of FIG. 7.

FIG. 9 is a cross-sectional view taken along line II-II′ of FIG. 7.

FIG. 10 to FIG. 13 are cross-sectional views illustrating a method of manufacturing a display device according to an embodiment.

FIG. 14 is a block diagram illustrating an electronic device according to an embodiment.

FIG. 15 is a view illustrating an example in which the electronic device of FIG. 14 is implemented as a smartphone.

FIG. 16 is an exploded perspective view of the electronic device of FIG. 15.

### DETAILED DESCRIPTION

Various example embodiments will be described more fully hereinafter with reference to the accompanying drawings, in which some example embodiments are shown. The present invention may, however, be embodied in many different forms and should not be construed as limited to the example embodiments set forth herein. Rather, these example embodiments are provided such that this disclosure will be thorough and complete, and will fully convey the scope of the present invention to those skilled in the art. In the drawings, the sizes and relative sizes of layers and regions may be exaggerated for clarity.

In the disclosure, various modifications can be made, various forms can be used, and specific embodiments will be illustrated in the drawings and described in detail in the text. However, this is not intended to limit the disclosure to a specific form disclosed, and it will be understood that all changes, equivalents, or substitutes which fall in the spirit and technical scope of the disclosure should be included.

It will be understood that, although the terms “first”, “second”, “first-first”, “second-first” etc. may be used herein to describe various elements, these elements should not be limited by these terms. These terms are used to distinguish one element from another. Thus, a first element discussed below could be termed a second element without departing from the teachings of the present invention. As used herein, the term “and/or” includes any and all combinations of one or more of the associated listed items.

It will be understood that when an element is referred to as being “connected” or “coupled” to another element, it can be directly connected or coupled to the other element or intervening element(s) may be present. In contrast, when an element is referred to as being “directly connected” or “directly coupled” to another element, there are no intervening elements present. Other words used to describe the relationship between elements should be interpreted in a like fashion (e.g., “between” versus “directly between,” “adjacent” versus “directly adjacent,” etc.).

The terminology used herein is for the purpose of describing particular example embodiments only and is not intended to be limiting of the present invention. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, embodiments will be described in detail with reference to the accompanying drawings. The same reference numerals are used for the same components in the drawings, and redundant descriptions of the same components will be omitted.

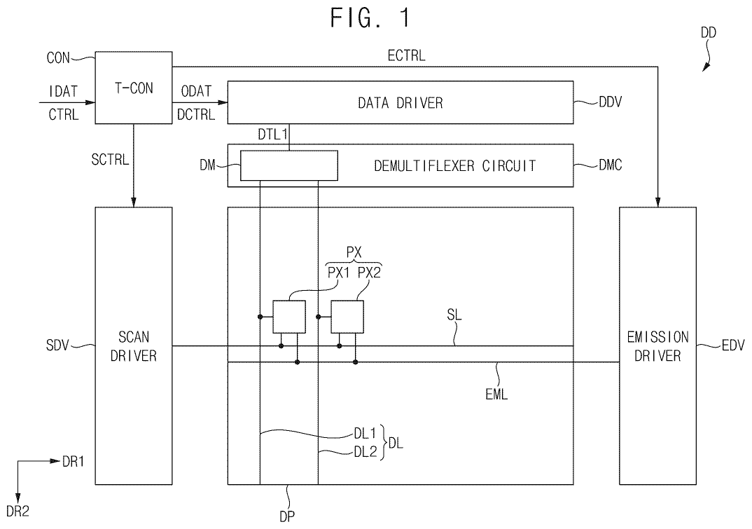

FIG. 1 is a block diagram illustrating a display device according to an embodiment.

Referring to FIG. 1, a display device DD according to an embodiment may include a display panel DP, a driving controller CON, a scan driver SDV, a data driver DDV, a demultiplexer circuit DMC, and an emission driver EDV.

The display panel DP may include a plurality of pixels PX, a plurality of scan lines SL, a plurality of emission control lines EML, and a plurality of data lines DL. In an embodiment, the pixels PX may be disposed in a first direction DR1 and a second direction DR2 crossing the first direction DR1.

Each of the pixels PX may be electrically connected to one of the scan lines SL, one of the emission control lines EML, and one of the data lines DL. For example, a first pixel PX1 may be electrically connected to a first data line DL1, and a second pixel PX2 may be electrically connected to a second data line DL2.

The driving controller CON may receive input image data IDAT and an input control signal CTRL from an external device. For example, the input image data IDAT may include red image data, green image data, and blue image data. For example, the input image data IDAT may include white image data. For example, the input image data IDAT may include magenta image data, yellow image data, and cyan image data. The input control signal CTRL may include a master clock signal and a data enable signal. The input control signal CTRL may further include a vertical synchronization signal and a horizontal synchronization signal.

The driving controller CON may generate a scan control signal SCTRL, a data control signal DCTRL, an emission control signal ECTRL, and output image data ODAT based on the input image data IDAT and the input control signal CTRL.

The driving controller CON may generate the scan control signal SCTRL for controlling the operation of the scan driver SDV based on the input control signal CTRL. The driving controller CON may output the scan control signal SCTRL to the scan driver SDV. The scan control signal SCTRL may include a vertical start signal and a scan clock signal.

The drive controller CON may generate the data control signal DCTRL for controlling the operation of the data driver DDV based on the input control signal CTRL. The drive controller CON may output the data control signal DCTRL to the data driver DDV. The data control signal DCTRL may include a horizontal start signal and a load signal.

The driving controller CON may generate the output image data ODAT based on input image data IDAT. The driving controller CON may output the output image data ODAT to the data driver DDV.

The driving controller CON may generate the emission control signal ECTRL for controlling the operation of the emission driver EDV based on the input control signal CTRL. The driving controller CON may output the emission control signal ECTRL to the emission driver EDV.

The scan driver SDV may generate scan signals based on the scan control signal SCTRL received from the drive controller CON. The scan driver SDV may output the scan signals to the scan lines SL.

The data driver DDV may generate data signals based on the output image data ODAT and the data control signal DCTRL. For example, the data driver DDV may generate the data signals corresponding to the output image data ODAT, and may output the data signals based on the data control signal DCTRL. The data driver DDV may output the data signals to the demultiplexer circuit DMC through data transmission lines. For example, the data driver DDV may be implemented with one or more integrated circuits.

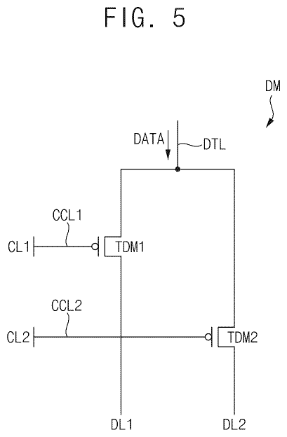

The demultiplexer circuit DMC may transmit the data signals to data lines DL. For example, the demultiplexer circuit DMC may time-divide the data signals and may transmit the data signals. In an embodiment, the demultiplexer circuit DMC may include a plurality of demultiplexers DM. Each of the demultiplexers DM may time-divide the received data signal and may transmit them to the data lines DL. For example, the demultiplexer DM may receive the data signal from the data driver DDV through a first data transmission line DTL1, and may sequentially transmit the data signal to the first data line DL1 and the second data line DL2. This will be described in detail later with reference to FIG. 5.

The emission driver EDV may generate emission control signals based on the emission control signal ECTRL received from the driving controller CON. The emission driver EDV may output the emission control signals to the emission control lines EML.

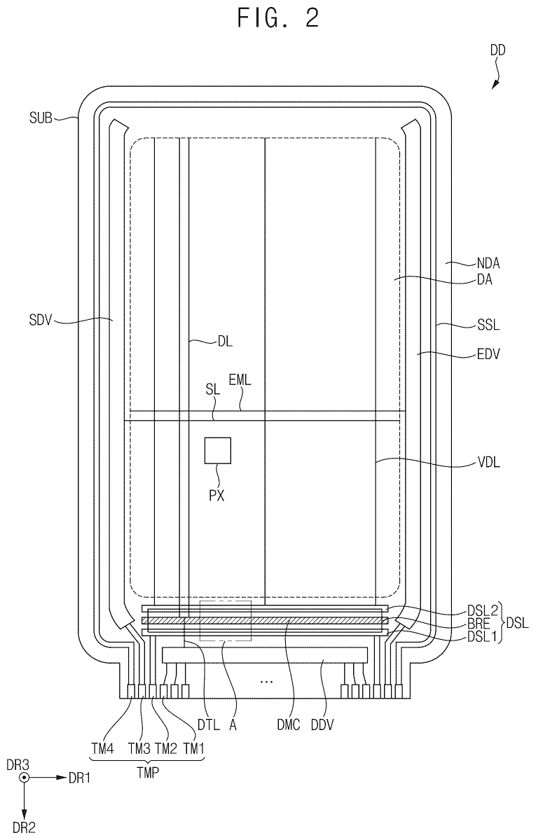

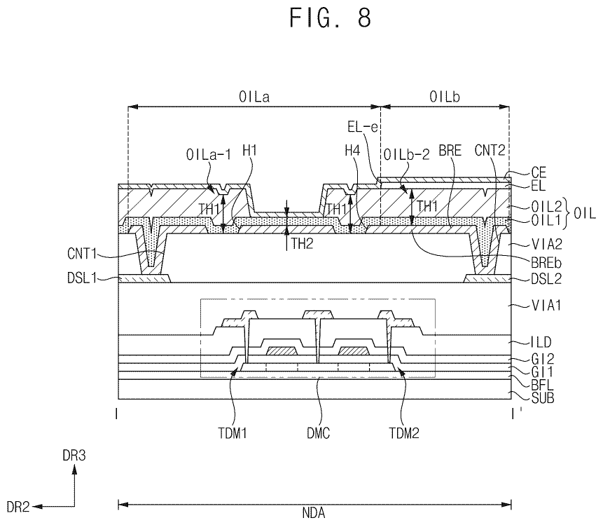

FIG. 2 is a plan view illustrating a display device according to an embodiment. As used herein, the “plan view” is a view in a thickness direction (i.e., third direction DR3) of the display device (or substrate SUB, See FIG. 8).

Referring to FIG. 2, in an embodiment, the display device DD may display an image in a third direction DR3 through a display surface defined by the first direction DR1 and the second direction DR2. The third direction DR3 may be substantially parallel to a normal direction of the display surface. The display surface may correspond to an upper surface or (a front surface) of the display device DD.

In an embodiment, the display device DD may include a substrate 100, the pixels PX, the scan driver SDV, the data driver DDV, the emission driver EDV, a terminal portion TMP, the demultiplexer circuit DMC, a driving voltage supply line DSL, and a common voltage supply line SSL.

The substrate 100 may include a display area DA and a non-display area NDA. The display area DA may display the image. In an embodiment, in a plan view, the display area DA may have a rectangular shape, and corners of the display area DA may each have rounded curved shape, but the present invention is not limited thereto. The pixels PX, the scan lines SL, the data lines DL, the emission control lines EML, and driving voltage lines VDL may be disposed in the display area DA.

The non-display area NDA may be located outside the display area DA. For example, the non-display area NDA may surround the display area DA in a plan view. In an embodiment, a portion of the non-display area NDA may be bent.

The scan driver SDV, the data driver DDV, and the emission driver EDV may be disposed in the non-display area NDA. FIG. 2 illustrates that the scan driver SDV is disposed on a left side of the display area DA and the emission driver EDV is disposed on a right side of the display area DA, but this is an example and the present invention is not limited thereto. For example, a first scan driver and a first emission driver may be disposed on the left side of the display area DA, and a second scan driver and a second emission driver may be disposed on the right side of the display area DA. The data driver DDV may be disposed to be spaced apart from the display area DA in the second direction DR2.

The terminal portion TMP may be disposed on one end portion of the substrate 100, and may include a plurality of terminals TM1, TM2, TM3, and TM4. The terminal portion TMP may be electrically connected to a bump portion of a circuit board attached on the one end portion of the substrate 100. For example, signals for controlling the operation of the data driver DDV (e.g., the data control signal DCTRL and the output image data ODAT of FIG. 1) may be transmitted to the data driver DDV through the first terminal TM1. For example, a driving voltage may be applied to the driving voltage supply line DSL through the second terminal TM2. For example, a signal for controlling the operation of the scan driver SDV (e.g., the scan control signal SCTRL of FIG. 1) may be transmitted to the scan driver SDV through the third terminal TM3. For example, a common voltage may be applied to the common voltage supply line SSL through the fourth terminal TM4.

The demultiplexer circuit DMC may be disposed in the non-display area NDA. The demultiplexer circuit DMC may be disposed between the display area DA and the data driver DDV in a plan view. The demultiplexer circuit DMC may receive the data signals from the data driver DDV through data transmission lines DTL. The demultiplexer circuit DMC may time-divide the data signals and may transmit them to the data lines DL.

In an embodiment, in a plan view, the demultiplexer circuit DMC may be disposed between a fan-out test circuit and a lighting test circuit in the non-display area NDA. For example, the fan-out test circuit may be disposed between the data driver DDV and the demultiplexer circuit DMC in a plan view. For example, the lighting test circuit may be disposed between the demultiplexer circuit DMC and the display area DA in a plan view.

The driving voltage supply line DSL may be disposed in the non-display area NDA. In an embodiment, the driving voltage supply line DSL may be disposed between the display area DA and the data driver DDV in a plan view. The driving voltage supply line DSL may provide the driving voltage to the pixels PX through the driving voltage lines VDL. In an embodiment, the driving voltage lines VDL may each extend in the second direction DR2, and may be disposed in the first direction DR1.

In an embodiment, the driving voltage supply line DSL may overlap the demultiplexer circuit DMC in a plan view. The driving voltage supply line DSL may include a first driving voltage supply line DSL1, a second driving voltage supply line DSL2, and a bridge electrode BRE.

The first driving voltage supply line DSL1 may extend in the first direction DR1. The first driving voltage supply line DSL1 may be disposed between the display area DA and the data driver DDV in a plan view. The first driving voltage supply line DSL1 may be disposed between the demultiplexer circuit DMC and the data driver DDV in a plan view. The driving voltage may be applied to the first driving voltage supply line DSL1 through the second terminal TM2.

The second driving voltage supply line DSL2 may extend in the first direction DR1. The second driving voltage supply line DL2 may be disposed between the display area DA and the first driving voltage supply line DSL1 in a plan view. In a plan view, the second driving voltage supply line DSL2 may be spaced apart from the display area DA in the second direction DR2, and may be spaced apart from the first driving voltage supply line DSL1 in a direction opposite to the second direction DR2. The second driving voltage supply line DL2 may be disposed between the display area DA and the demultiplexer circuit DMC in a plan view. The second driving voltage supply line DSL2 may be connected to the driving voltage lines VDL extending from the second driving voltage supply line DSL2 to the display area DA.

In a plan view, the first driving voltage supply line DSL1 and the second driving voltage supply line DSL2 may be spaced apart from each other in the second direction DR2 with the demultiplexer circuit DMC therebetween. The first driving voltage supply line DSL1 may be spaced apart from the demultiplexer circuit DMC in the second direction DR2 in a plan view. The second driving voltage supply line DSL2 may be spaced apart from the demultiplexer circuit DMC in the direction opposite to the second direction DR2 in a plan view. That is, each of the first driving voltage supply line DSL1 and the second driving voltage supply line DSL2 may not overlap the demultiplexer circuit DMC in a plan view.

The bridge electrode BRE may be disposed on the first driving voltage supply line DSL1, the second driving voltage supply line DSL2, and the demultiplexer circuit DMC. The bridge electrode BRE may overlap the demultiplexer circuit DMC in a plan view, and may electrically connect the first driving voltage supply line DSL1 and the second driving voltage supply line DSL2. For example, a first end portion of the bridge electrode BRE may be connected to the first driving voltage supply line DSL1, a second end portion of the bridge electrode BRE may be connected to the second driving voltage supply line DSL2, and a central portion of the bridge electrode BRE may overlap the demultiplexer circuit DMC in a plan view. The driving voltage may be applied to the second driving voltage supply line DSL2 through the bridge electrode BRE.

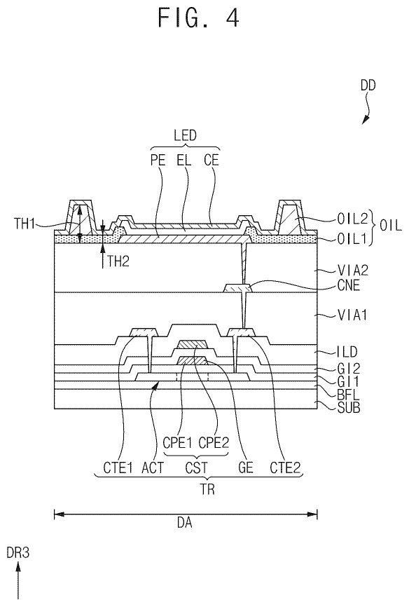

The common voltage supply line SSL may be disposed in the non-display area NDA. In an embodiment, the common voltage supply line SSL may form a loop with one end open side and extend along edges of the substrate 100 excluding an edge adjacent the terminal portion TMP, but the present invention is not limited thereto. The common voltage supply line SSL may provide a common voltage to the pixels PX. For example, a common electrode CE (see FIG. 4) of a light emitting element LED may be connected to the common voltage supply line SSL in the non-display area NDA.

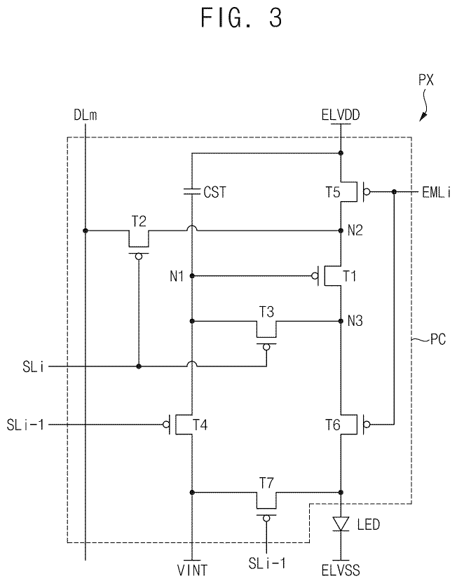

FIG. 3 is a schematic diagram of an equivalent circuit of a pixel according to an embodiment.

Each of the pixels PX may include a pixel circuit PC and a light emitting element LED. The pixel circuits PC may have substantially the same structure. Hereinafter, a pixel PX connected to a m-th data line DLm and a i-th scan line SLi will be described.

Referring to FIG. 3, the pixel circuit PC may include first to seventh pixel transistors T1, T2, T3, T4, T5, T6, and T7, and a storage capacitor CST.

The first pixel transistor T1 may include a gate electrode connected to a first node N1, a first electrode connected to a second node N2, and a second electrode connected to a third node N3.

The second pixel transistor T2 may include a gate electrode connected to the i-th scan line SLi, a first electrode connected to the m-th data line DLm, and a second electrode connected to the second node N2.

The third pixel transistor T3 may include a gate electrode connected to the i-th scan line SLi, a first electrode connected to the first node N1, and a second electrode connected to the third node N3.

The fourth pixel transistor T4 may include a gate electrode connected to a i−1th scan line SLi−1, a first electrode to which an initialization signal VINT is applied, and a second electrode connected to the first node N1.

The fifth pixel transistor T5 may include a gate electrode connected to a i-th emission control line EMLi, a first electrode to which the driving voltage ELVDD is applied, and a second electrode connected to the second node N2. The driving voltage ELVDD may be a high power supply voltage.

The sixth pixel transistor T6 may include a gate electrode connected to the i-th emission control line EMLi, a first electrode connected to the third node N3, and a second electrode connected to a pixel electrode (an anode, PE of FIG. 4) of the light emitting element LED.

The seventh pixel transistor T7 may include a gate electrode connected to the i−1th scan line SLi−1, a first electrode to which the initialization signal VINT is applied, and a second electrode connected to the pixel electrode of the light emitting element LED.

The storage capacitor CST may include a first electrode to which the driving voltage ELVDD is applied and a second electrode connected to the first node N1.

The light emitting element LED may include the pixel electrode and the common electrode (a cathode, CE of FIG. 4) to which the common voltage ELVSS is applied. The common voltage ELVSS may be a low power supply voltage. The light emitting element LED may emit light based on a driving current provided from the pixel circuit PC. For example, the light emitting element LED may include an organic light emitting diode, an inorganic light emitting diode, a quantum dot light emitting diode, a micro light emitting diode, or the like.

In FIG. 3, the first to seventh pixel transistors T1, T2, T3, T4, T5, T6, and T7 are illustrated as p-channel metal oxide semiconductor (“PMOS”) transistors, but embodiments are not limited thereto. For example, the third pixel transistor T3 and the fourth pixel transistor T4 may be n-channel metal oxide semiconductor (“NMOS”) transistors, and the other pixel transistors may be PMOS transistors. For another example, all of the first to seventh pixel transistors T1, T2, T3, T4, T5, T6, and T7 may be NMOS transistors.

In addition, the number of pixel transistors and the number of capacitors illustrated in FIG. 3 is only an example and may be variously changed according to embodiments.

FIG. 4 is a cross-sectional view illustrating a display device according to an embodiment.

FIG. 4 is a cross-sectional view of the display area DA of the display device DD.

Referring to FIG. 4, the display device DD may include the substrate SUB, a buffer layer BFL, a transistor TR, the storage capacitor CST, a first gate insulating layer GI1, a second gate insulating layer GI2, an interlayer insulating layer ILD, a first via-insulating layer VIA1, a connection electrode CNE, a second via-insulating layer VIA2, the light emitting element LED, and an organic insulating layer OIL. The transistor TR may include an active layer ACT, a gate electrode GE, a first contact electrode CTE1, and a second contact electrode CTE2. For example, the transistor TR of FIG. 4 may be the sixth pixel transistor T6 of FIG. 3. The storage capacitor CST may include a first capacitor electrode CPE1 and a second capacitor electrode CPE2. The light emitting element LED may include the pixel electrode PE, an emission layer EL, and the common electrode CE.

The substrate SUB may form a base of the display device DD. The substrate SUB may be an insulating substrate including or formed of a transparent or a non-transparent material. In an embodiment, the substrate SUB may be flexible, and the display device DD may be a flexible display device. In another embodiment, the substrate SUB may be rigid, and the display device DD may be a rigid display device.

The buffer layer BFL may be disposed on the substrate SUB. The buffer layer BFL may prevent or reduce impurities, such as oxygen or moisture, from penetrating into an upper portion of the substrate SUB through the substrate SUB. The buffer layer BFL may include an inorganic material, such as a silicon compound, a metal oxide, or the like. For example, the buffer layer BFL may include silicon oxide (SiOₓ), silicon nitride (SiNₓ), silicon oxynitride (SiOₓN_{y}), aluminum oxide (AlOₓ), aluminum nitride (AlNₓ), tantalum oxide (TaOₓ), hafnium oxide (HfOₓ), zirconium oxide (ZrOₓ), titanium oxide (TiOₓ), or the like. These may be used alone or in combination with each other. The buffer layer BFL may have a single layer structure or a multi-layer structure including a plurality of insulating layers.

The active layer ACT may be disposed on the buffer layer BFL. The active layer ACT may include an oxide semiconductor, a silicon semiconductor, an organic semiconductor, or the like. For example, the oxide semiconductor may include at least one selected from oxides of indium (In), gallium (Ga), tin (Sn), zirconium (Zr), vanadium (V), hafnium (Hf), cadmium (Cd), germanium (Ge), chromium (Cr), titanium (Ti), and zinc (Zn). The silicon semiconductor may include an amorphous silicon, a polycrystalline silicon, or the like. The active layer ACT may include a first contact area, a second contact area, and a channel area located between the first contact area and the second contact area. Each of the first contact area and the second contact area may have higher conductivity than a conductivity of the channel area.

The first gate insulating layer GI1 may be disposed on the active layer ACT. The first gate insulating layer GI1 may cover the active layer ACT on the buffer layer BFL. The first gate insulating layer GI1 may include an inorganic insulating material.

The gate electrode GE may be disposed on the first gate insulating layer GI1. The gate electrode GE may overlap the channel area of the active layer ACT. The gate electrode GE may function as the first capacitor electrode CPE1 of the storage capacitor CST. The gate electrode GE may include a conductive material, such as a metal, an alloy, a conductive metal nitride, a conductive metal oxide, a transparent conductive material, or the like. For example, the gate electrode GE may include gold (Au), silver (Ag), aluminum (Al), platinum (Pt), nickel (Ni), titanium (Ti), palladium (Pd), magnesium (Mg), calcium (Ca), lithium (Li), chromium (Cr), tantalum (Ta), tungsten (W), copper (Cu), molybdenum (Mo), scandium (Sc), neodymium (Nd), iridium (Ir), alloys containing aluminum, alloys containing silver, alloys containing copper, alloys containing molybdenum, aluminum nitride (AlNₓ), tungsten nitride (WNₓ), titanium nitride (TiNₓ), chromium nitride (CrNₓ), tantalum nitride (TaNₓ), strontium ruthenium oxide (SrRuOₓ), zinc oxide (ZnOₓ), indium tin oxide (ITO), tin oxide (SnOₓ), indium oxide (InOₓ), gallium oxide (GaOₓ), indium zinc oxide (IZO), or the like. These may be used alone or in combination with each other. The gate electrode GE may have a single layer structure or a multi-layer structure including a plurality of conductive layers.

The second gate insulating layer GI2 may be disposed on the gate electrode GE. The second gate insulating layer GI2 may cover the gate electrode GE on the first gate insulating layer GI1. The second gate insulating layer GI2 may include an inorganic insulating material.

The second capacitor electrode CPE2 may be disposed on the second gate insulating layer GI2. The second capacitor electrode CPE2 may overlap the first capacitor electrode CPE1 in a plan view. The second capacitor electrode CPE2 may include a conductive material, such as a metal, an alloy, a conductive metal nitride, a conductive metal oxide, a transparent conductive material, or the like.

The interlayer insulating layer ILD may be disposed on the second capacitor electrode CPE2. The interlayer insulating layer ILD may cover the second capacitor electrode CPE2 on the second gate insulating layer GI2. The interlayer insulating layer ILD may include an inorganic insulating material and/or an organic insulating material.

The first contact electrode CTE1 and the second contact electrode CTE2 may be disposed on the interlayer insulating layer ILD. The first contact electrode CTE1 and the second contact electrode CTE2 may be connected to the first contact area and the second contact area of the active layer ACT, respectively. Each of the first contact electrode CTE1 and the second contact electrode CTE2 may include a conductive material.

The first via-insulating layer VIA1 may be disposed on the first contact electrode CTE1 and the second contact electrode CTE2. The first via insulation layer VIA1 may cover the first contact electrode CTE1 and the second contact electrode CTE2 on the interlayer insulation layer ILD. The first via-insulating layer VIA1 may include an organic insulating material. For example, the first via-insulating layer VIA1 may include a photoresist, a polyacryl-based resin, a polyimide-based resin, a polyamide-based resin, a siloxane-based resin, an acrylic resin, an epoxy-based resin, or the like. These may be used alone or in combination with each other.

The connection electrode CNE may be disposed on the first via-insulating layer VIA1. The connection electrode CNE may include a conductive material. The connection electrode CNE may be connected to the second contact electrode CTE2 through a contact hole penetrating the first via-insulating layer VIA1.

The second via insulation layer VIA2 may be disposed on the connection electrode CNE. The second via insulation layer VIA2 may cover the connection electrode CNE on the first via insulation layer VIA1. The second via insulation layer VIA2 may include an organic insulating material.

The pixel electrode PE may be disposed on the second via-insulating layer VIA2. The pixel electrode PE may include a conductive material. The pixel electrode PE may be connected to the connection electrode CNE through a contact hole penetrating the second via-insulating layer VIA2. Accordingly, the pixel electrode PE may be electrically connected to the transistor TR. For example, the pixel electrode PE may be the anode of the light emitting element LED.

The organic insulating layer OIL may be disposed on the pixel electrode PE. The organic insulating layer OIL may include an organic insulating material. In an embodiment, the organic insulating layer OIL may further include a light blocking material having a black color. The organic insulating layer OIL may include a first layer OIL1 and a second layer OIL2.

In the display area DA, the first layer OIL1 may cover a peripheral portion of the pixel electrode PE, and may define a pixel opening exposing a central portion of the pixel electrode PE. An emission area may be defined by the pixel opening. The first layer OIL1 disposed in the display area DA may be referred to as a pixel defining layer.

In the display area DA, the second layer OIL2 may be disposed outside the pixel electrode PE. The second layer OIL2 may be disposed on the first layer OIL1. In an embodiment, in a non-emission area of the display area DA, a plurality of second layers OIL2 may be disposed to be spaced apart from each other on the first layer OIL1. For example, the second layer OIL2 may serve to support structures used in the manufacturing process of the display device DD (e.g., a fine metal mask (“FMM”) for forming the emission layer EL, or the like). The second layer OIL2 disposed in the display area DA may be referred to as a spacer.

In an embodiment, the first layer OIL1 and the second layer OIL2 of the organic insulating layer OIL1 may be substantially simultaneously formed using a halftone mask. That is, the organic insulating layer OIL may have a single layer structure in which the first layer OIL1 and the second layer OIL2 are integral. The organic insulating layer OIL may have a first thickness TH1 in an area where both the first layer OIL1 and the second layer OIL2 are disposed, and may have a second thickness TH2 less than the first thickness TH1 in an area where only the first layer OIL1 is disposed and the second layer OIL2 is not disposed. That is, the organic insulating layer OIL may be formed to include a relatively thick portion and a relatively thin portion using the halftone mask.

The emission layer EL may be disposed on the pixel electrode PE and the organic insulating layer OIL. At least a portion of the emission layer EL may disposed in the pixel opening of the first layer OIL1 of the organic insulating layer OIL. In an embodiment, the emission layer EL may include at least one of an organic light emitting material or a quantum dot, but the present invention is not limited thereto.

In an embodiment, the organic light emitting material may include a low molecular weight organic compound or a high molecular weight organic compound. Examples of the low molecular weight organic compound may include copper phthalocyanine, N,N′-diphenylbenzidine, tris-(8-hydroxyquinoline)aluminum, or the like. Examples of the high molecular weight organic compound may include poly(3,4-ethylenedioxythiophene), polyaniline, poly-phenylenevinylene, polyfluorene, or the like. These materials can be used alone or in a combination thereof.

In an embodiment, the quantum dot may include a core including a Group II-VI compound, a Group III-V compound, a Group IV-VI compound, a Group IV element, and/or a Group IV compound. In an embodiment, the quantum dot may have a core-shell structure including the core and a shell surrounding the core. The shell may act as a protection layer preventing the core from being chemically denatured to maintain its semiconductor characteristics and may act as a charging layer for imparting electrophoretic characteristics to the quantum dot.

The common electrode CE may be disposed on the emission layer EL. The common electrode CE may include a conductive material. In an embodiment, the common electrode CE may be disposed the entire display area DA, and may extend from the display area DA to a portion of the non-display area NDA. As described above, the common electrode CE may be connected to the common voltage supply line SSL of FIG. 2 in the non-display area NDA. For example, the common electrode CE may be the cathode of the light emitting element LED.

In an embodiment, the light emitting element LED may further include a first functional layer disposed between the pixel electrode PE and the emission layer EL and/or a second functional layer disposed between the emission layer EL and the common electrode CE. For example, the first functional layer may include a hole injection layer, a hole transport layer, or the like, and the second functional layer may include an electron transport layer, an electron injection layer, or the like.

In an embodiment, various layers, such as a thin film encapsulation layer, a touch sensing layer, a color filter layer, a light collecting layer, or the like may be disposed on the common electrode CE.

FIG. 5 is a schematic diagram of an equivalent circuit of a demultiplexer according to an embodiment.

In FIG. 5, a case where one data transmission line DTL is connected to one demultiplexer DM and two data lines DL1 and DL2 are connected to one mux demultiplexer DM will be described. For example, the first data line DL2 and the second data line DL2 may be connected to one demultiplexer DM. However, the present invention is not limited thereto.

Referring to FIG. 5, the demultiplexer DM may include a first distribution transistor TDM1 and a second distribution transistor TDM2.

The first distribution transistor TDM1 may include a gate electrode connected to a first distribution selection signal line CCL1, a first electrode to which the data signal DATA is applied, and a second electrode connected to the first data line DL1. A first distribution selection signal CL1 may be applied to the gate electrode of the first distribution transistor TDM1 through the first distribution selection signal line CCL1. When the first distribution selection signal CL1 is applied to the gate electrode of the first distribution transistor TDM1, the first distribution transistor TDM1 may be turned on and the data signal DATA may be output to the first data line DL1. That is, the first distribution transistor TDM1 may output the data signal DATA to the first data line DL1 in response to the first distribution selection signal CL1.

The second distribution transistor TDM2 may include a gate electrode connected to a second distribution selection signal line CCL2, a first electrode to which the data signal DATA is applied, and a second electrode connected to the second data line DL2. A second distribution selection signal CL2 may be applied to the gate electrode of the second distribution transistor TDM2 through the second distribution selection signal line CCL2. When the second distribution selection signal CL2 is applied to the gate electrode of the second distribution transistor TDM2, the second distribution transistor TDM2 may be turned on and the data signal DATA may be output to the second data line DL2. That is, the second distribution transistor TDM2 may output the data signal DATA to the second data line DL2 in response to the second distribution selection signal CL2.

The first distribution transistor TDM1 and the second distribution transistor TDM2 may be selectively turned on by the first distribution selection signal CL1 and the second distribution selection signal CL2. Accordingly, the demultiplexer DM may selectively provide the data signal DATA to the two data lines DL1 and DL2.

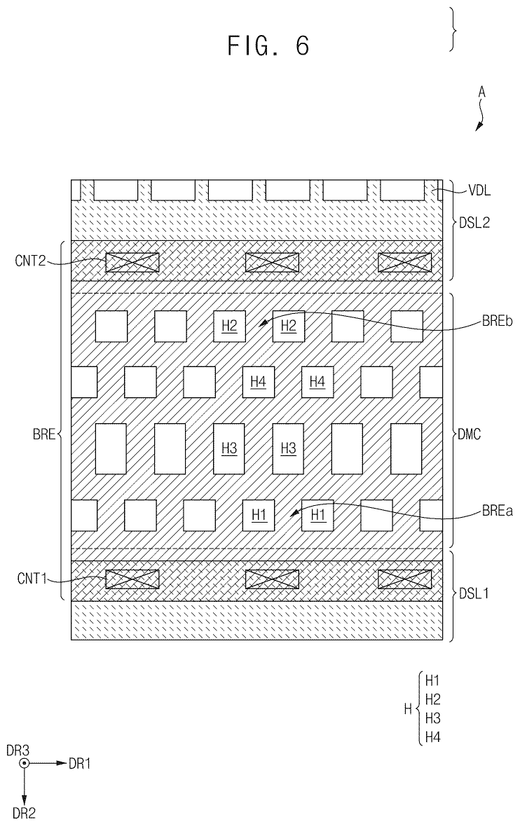

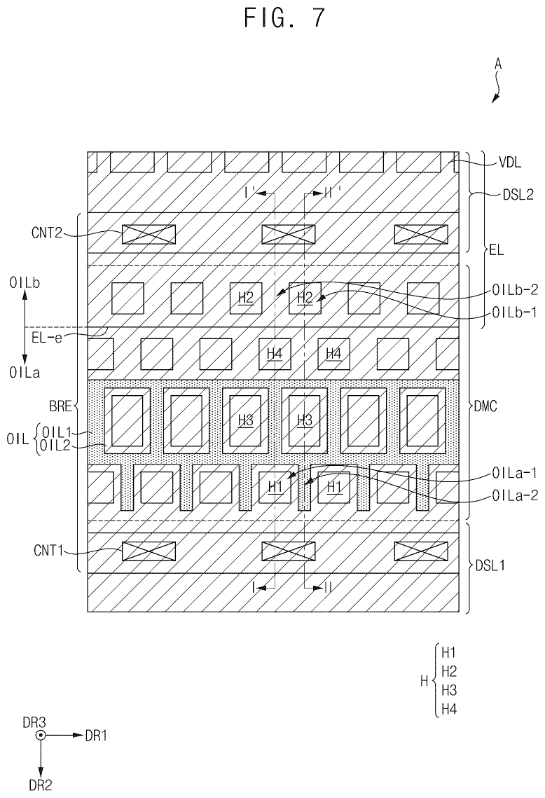

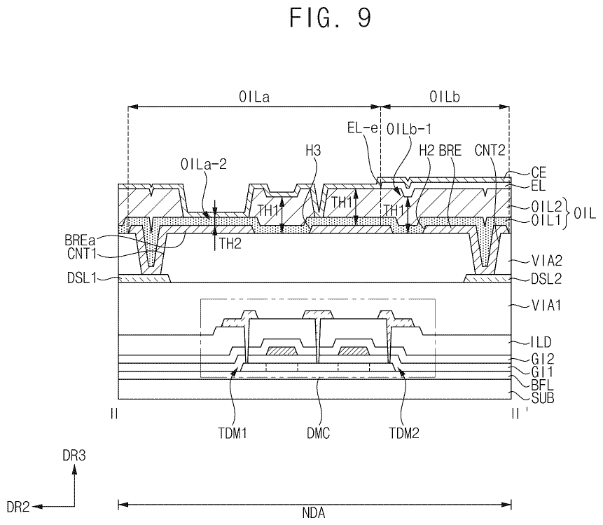

FIG. 6 and FIG. 7 are enlarged plan views illustrating an example of an area A of FIG. 2. FIG. 8 is a cross-sectional view taken along line I-I′ of FIG. 7. FIG. 9 is a cross-sectional view taken along line II-II′ of FIG. 7.

FIGS. 6 and 7 illustrate some components of the display device DD. For example, FIG. 6 may illustrate the first driving voltage supply line DSL1, the second driving voltage supply line DSL2, the bridge electrode BRE, and the driving voltage lines VDL. FIG. 7 may illustrate that the organic insulating layer OIL and the emission layer EL are further disposed on the components illustrated in FIG. 6.

Referring to FIG. 2 and FIGS. 6 to 9, the first driving voltage supply line DSL1 may be spaced apart from the demultiplexer circuit DMC in the second direction DR2 in a plan view. The second driving voltage supply line DSL2 may be spaced apart from the demultiplexer circuit DMC in the direction opposite to the second direction DR2 in a plan view.

The bridge electrode BRE may be disposed on the first driving voltage supply line DSL1, the second driving voltage supply line DSL2, and the demultiplexer circuit DMC. The bridge electrode BRE may overlap the demultiplexer circuit DMC in a plan view, and may electrically connect the first driving voltage supply line DSL1 and the second driving voltage supply line DSL2.

In an embodiment, the bridge electrode BRE may be in a different layer from the first driving voltage supply line DSL1 and the second driving voltage supply line DSL2. For example, the first driving voltage supply line DSL, the second driving voltage supply line DSL2, and the connection electrode CNE of FIG. 4 may be in the same layer, and the bridge electrode BRE and the pixel electrode PE of FIG. 4 may be in the same layer. The first driving voltage supply line DSL, the second driving voltage supply line DSL2, and the connection electrode CNE of FIG. 4 may include the same material and may be substantially simultaneously formed as each other. The bridge electrode BRE and the pixel electrode PE of FIG. 4 may include the same material and may be substantially simultaneously formed as each other. The first driving voltage supply line DSL1 and the second driving voltage supply line DSL2 may be disposed between the first via insulation layer VIA1 and the second via insulation layer VIA2, and the bridge electrode BRE may be disposed between the second via insulation layer VIA2 and the organic insulation layer OIL. However, this is an example and the present invention is not limited thereto.

In an embodiment, the bridge electrode BRE may include a first end portion overlapping the first driving voltage supply line DSL1 in a plan view, a second end portion overlapping the second driving voltage supply line DSL2 in a plan view, and a central portion connecting the first end portion and the second end portion.

For example, the first end portion of the bridge electrode BRE may be connected to the first driving voltage supply line DSL1 through a first contact hole CNT1 penetrating the second via-insulating layer VIA2. The second end portion of the bridge electrode BRE may be connected to the second driving voltage supply line DSL2 through a second contact hole CNT2 penetrating the second via-insulating layer VIA2. The central portion of the bridge electrode BRE may overlap the demultiplexer circuit DMC in a plan view. For example, the demultiplexer circuit DMC may be disposed between the substrate SUB and the first via-insulating layer VIA1. The demultiplexer circuit DMC may include the demultiplexers DM each including the first distribution transistor TDM1 and the second distribution transistor TDM2 (see FIG. 5).

In an embodiment, the central portion of the bridge electrode BRE may define a plurality of holes H for outgassing in the first and second via-insulating layers VIA1 and VIA2. In a plan view, the holes H may be located between the first driving voltage supply line DSL1 and the second driving voltage supply line DSL2, and may be spaced apart from each other. For example, each of the holes H may have a rectangular planar shape, but the present invention is not limited thereto. The holes H may provide a path through which gas included in the first and second via-insulating layers VIA1 and VIA2 under the bridge electrode BRE can be discharged to the outside.

In an embodiment, the plurality of holes H may include first holes H1, second holes H2, third holes H3, and fourth holes H4, which are located in different rows as each other. The first holes H1 may be located in a row among the rows which is closest to the first driving voltage supply line DSL1. In a plan view, the first holes H1 may be adjacent to the first driving voltage supply line DSL1 in the direction opposite to the second direction DR2, and may be arranged along the first direction DR1. The second holes H2 may be located in a row among the rows which is closest to the second driving voltage supply line DSL2. In a plan view, the second holes H2 may be adjacent to the second driving voltage supply line DSL2 in the second direction DR2, and may be arranged along the first direction DR1. In a plan view, the third holes H3 and the fourth holes H4 may be located between the first holes H1 and the second holes H2. In a plan view, the third holes H3 may be adjacent to the first holes H1 in the direction opposite to the second direction DR2, and the fourth holes H4 may be adjacent to the second holes H2 in the second direction DR2.

In an embodiment, the organic insulating layer OIL may also be disposed on the first driving voltage supply line DSL1, the second driving voltage supply line DSL2, and the bridge electrode BRE. In addition, the emission layer EL which is disposed in the display area DA may extend from the display area DA to the non-display area NDA such that one end portion of the emission layer EL in the non-display area NDA overlaps a portion of the bridge electrode BRE (e.g., an upper side portion of the bridge electrode BRE in FIG. 7) in a plan view. For example, the emission layer EL may be formed in the display area DA by a deposition process using a deposition mask (e.g., FMM, or the like), and may also be formed in a portion of the non-display area NDA such that an edge EL-e of the emission layer EL in the non-display area NDA is located on the bridge electrode BRE, in consideration of a process margin. That is, in a plan view, the one end portion of the emission layer EL in the non-display area NDA may overlap the second driving voltage supply line DSL2, the portion of the bridge electrode BRE, and a portion of the demultiplexer circuit DMC.

In an embodiment, the one end portion of the emission layer EL in the non-display area NDA may overlap some of the holes H which are defined in the bridge electrode BRE in a plan view. For example, as illustrated in FIG. 7, in a plan view, the one end portion of the emission layer EL in the non-display area NDA may overlap the second holes H2, and may not overlap the first holes H1. That is, the first holes H1 may be spaced apart from the emission layer EL in a plan view. In addition, FIG. 7 illustrates that the one end portion of the emission layer EL in the non-display area NDA does not overlap the third holes H3 and the fourth holes H4 in a plan view, but the present invention is not limited thereto.

In an embodiment, the organic insulating layer OIL may include a first portion OILa adjacent to the first driving voltage supply line DSL1 and a second portion OILb adjacent to the second driving voltage supply line DSL2. The first portion OILa may be defined as a portion which overlaps the bridge electrode BRE and does not overlap the emission layer EL in a plan view (i.e., is spaced apart from the emission layer EL in a plan view), and the second portion OILb may be defined as a portion which overlaps the bridge electrode BRE and the emission layer EL in a plan view. The first portion OILa may be located in the second direction DR2 from the second portion OILb. The border between the first portion OILa and the second portion OILb may correspond to the edge EL-e of the emission layer EL.

In an embodiment, in a plan view, the first portion OILa of the organic insulating layer OIL may overlap the first holes H1, the third holes H3, and the fourth holes H4, and may not overlap the second holes H2. In a plan view, the second portion OILb of the organic insulating layer OIL may overlap the second holes H2, and may not overlap the first holes H1, the third holes H3, and the fourth holes H4.

In an embodiment, an average thickness of the first portion OILa of the organic insulating layer OIL may be less than an average thickness of the second portion OILb of the organic insulating layer OIL. In addition, a thickness deviation in the first portion OILa of the organic insulating layer OIL may be greater than a thickness deviation in the second portion OILb of the organic insulating layer OIL.

As illustrated in FIGS. 6, 7 and 8, in an embodiment, a first-first portion OILa-1 of the first portion OILa of the organic insulating layer OIL, which overlaps one of the first holes H1 in a plan view, may have a first thickness TH1. The first-first portion OILa-1 may have a structure which includes the first layer OIL1 and the second layer OIL2. As described above, the first layer OIL1 and the second layer OIL2 may be integrally formed using a halftone mask.

As illustrated in FIGS. 6, 7 and 9, in an embodiment, a first-second portion OILa-2 of the first portion OILa of the organic insulating layer OIL, which overlaps a first portion BREa of the bridge electrode BRE between two adjacent first holes H1 in the first direction DR1 among the first holes H1 in a plan view, may have a second thickness TH2 less than the first thickness TH1. The first-second portion OILa-2 may have a structure which includes the first layer OIL1 and does not includes the second layer OIL2.

As illustrated in FIGS. 6, 7 and 9, in an embodiment, a second-first portion OILb-1 of the second portion OILb of the organic insulating layer OIL, which overlaps one of the second holes H2 in a plan view, may have the first thickness TH1. The second-first portion OILb-1 may have a structure which includes the first layer OIL1 and the second layer OIL2.

As illustrated in FIGS. 6, 7 and 8, in an embodiment, a second-second portion OILb-2 of the second portion OILb of the organic insulating layer OIL, which overlaps a second portion BREb of the bridge electrode BRE between two adjacent second holes H2 in the first direction DR1 among the second holes H2 in a plan view, may have the first thickness TH1. The second-second portion OILb-2 may have a structure which includes the first layer OIL1 and the second layer OIL2.

That is, according to embodiments, in an area which is adjacent to the first driving voltage supply line DSL1 and is far from the emission layer EL (e.g., near the first holes H1 arranged along the first direction DR1), the first portion OILa of the organic insulating layer OIL may have a structure in which portions each having the first thickness TH1 (i.e., including the first layer OIL1 and the second layer OIL2) and portions each having the second thickness TH2 less than the first thickness TH1 (i.e., including only the first layer OIL1) alternate with each other. Accordingly, an outgassing efficiency in the first and second via-insulating layers VIA1 and VIA2 under the bridge electrode BRE may be improved. In contrast, in an area which is adjacent to the second driving voltage supply line DSL2 and overlaps the emission layer EL (e.g., near the second holes H2 arranged along the first direction DR1), the second portion OILb of the organic insulating layer OIL may be formed to entirely have the first thickness TH1 (i.e., to include the first layer OIL1 and the second layer OIL2). That is, unlike an area which does not overlap the emission layer EL in a plan view, in an area which overlaps both the emission layer EL and the bridge electrode BRE in a plan view, the entire organic insulating layer OIL under the emission layer EL may be formed to be relatively thick.

For example, when an exposure amount in an exposure process for forming the organic insulating layer OIL is increased in order to remove residual layers of the first and second via-insulating layers VIA1 and VIA2, a portion of the organic insulating layer OIL which is formed relatively thinly (i.e., includes only the first layer OIL1) may easily be lost. If a portion of the organic insulating layer OIL, which is between the bridge electrode BRE to which the driving voltage is applied and the emission layer EL, is lost, an abnormal light emission, in which the emission layer EL emits light on the bridge electrode BRE in the non-display area NDA, may occur. However, according to embodiments, since the organic insulating layer OIL under the emission layer EL is formed to entirely have a thickness (i.e., to include the first layer OIL1 and the second layer OIL), which is relatively thick, in the area which overlaps the emission layer EL, the loss of the portion of the organic insulating layer OIL, which is between the bridge electrode BRE to which the driving voltage is applied and the emission layer EL, may be prevented or reduced. Accordingly, it is possible to prevent or reduce the abnormal light emission in which the emission layer EL emits light on the bridge electrode BRE in the non-display area NDA, thereby improving a reliability of the display device DD may be effectively improved.

The first portion OILa of the organic insulating layer OIL may be formed to have a structure in which portions each having the first thickness TH1, which is relatively thick, and portions each having the second thickness TH2, which is relatively thin, alternate with each other at least in some areas, and the entirety of the second portion OILb of the organic insulating layer OIL is formed to have the first thickness TH1, which is relatively thick, or higher such that the average thickness of the first portion OILa of the organic insulating layer OIL may be less than the average thickness of the second portion OILb of the organic insulating layer OIL. In addition, the thickness deviation in the first portion OILa of the organic insulating layer OIL may be greater than the thickness deviation in the second portion OILb of the organic insulating layer OIL.

In an embodiment, a portion of the first portion OILa of the organic insulating layer OIL, which is adjacent to the second portion OILb (i.e., adjacent to the emission layer EL), may be formed to have the first thickness TH1, which is relatively thick, (i.e., to include the first layer OIL1 and the second layer OIL2), similar to the second portion OILb. For example, as illustrated in FIGS. 7 to 9, near the fourth holes H4 arranged along the first direction DR1, a portion of the first portion OILa of the organic insulating layer OIL may have the overall first thickness TH1. For example, near the third holes H3 arranged along the first direction DR1, another portion of the first portion OILa of the organic insulating layer OIL may have a structure in which portions each having the first thickness TH1 and portions each having the second thickness TH2 less than the first thickness TH1 alternate with each other. For example, a range of the area, in which the organic insulating layer OIL is formed to entirely have the first thickness TH1, which is relatively thick, may be determined in consideration of the tolerance of the deposition mask used for forming the emission layer EL.

Although not illustrated in the drawing, the display device DD may further include a bridge pattern disposed in the non-display area NDA, disposed in the same layer as the pixel electrode PE and the bridge electrode BRE, and to which the common voltage is applied. For example, the bridge pattern disposed in the non-display area NDA may electrically connect the common voltage supply line SSL of FIG. 2 and the common electrode CE of FIG. 4. In addition, the emission layer EL may extend from the display area DA to the non-display area NDA such that a portion of the emission layer EL overlaps the bridge pattern in a plan view. Unlike the bridge electrode BRE to which the driving voltage is applied, even if a portion of the organic insulating layer OIL, which is between the bridge pattern to which the common voltage is applied and the emission layer EL, is lost, the emission layer EL may not emit light on the bridge pattern. Therefore, in order to further improve the outgassing efficiency in the first and second via-insulating layers VIA1 and VIA2, in an area which overlaps both the emission layer EL and the bridge pattern, the organic insulating layer OIL under the emission layer EL may have a structure in which portions each having the first thickness TH1 and portions each having the second thickness TH2 alternate with each other.

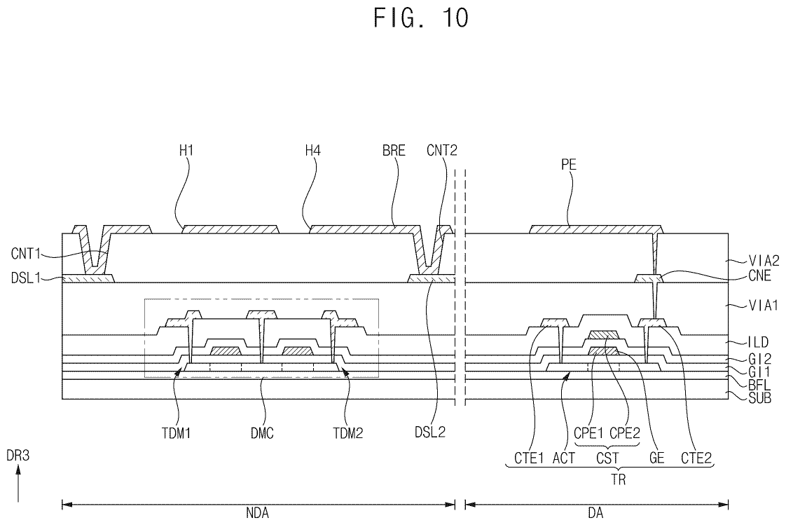

FIG. 10 to FIG. 13 are cross-sectional views illustrating a method of manufacturing a display device according to an embodiment.

For example, in each of FIGS. 10 to 13, the left cross-sectional view may correspond to FIG. 8, and the right cross-sectional view may correspond to FIG. 4. Hereinafter, an example of a method of manufacturing the display device DD of FIGS. 2 to 9 will be briefly described with reference to FIGS. 10 to 13. Hereinafter, description overlapping the described above description will be omitted or simplified.

Referring to FIG. 10, the buffer layer TR, the transistor TR, the storage capacitor CST, the demultiplexer circuit DMC, the first gate insulating layer GI1, the second gate insulating layer GI2, the interlayer insulating layer ILD, the first via-insulating layer VIA1, the connection electrode CNE, the first driving voltage supply line DSL1, the second driving voltage supply line DSL2, the a second via-insulating layer VIA2 may be formed on the substrate SUB. The transistor TR and the storage capacitor CST may be formed in the display area DA on the substrate SUB. The demultiplexer circuit DMC may be formed in the non-display area NDA on the substrate SUB.

The connection electrode CNE, the first driving voltage supply line DSL1, and the second driving voltage supply line DSL2 may be formed on the first via-insulating layer VIA1. The connection electrode CNE may be formed in the display area DA on the first via-insulating layer VIA1, and the first driving voltage supply line DSL1 and the second driving voltage supply line DSL2 may be formed in the non-display area NDA on the first via-insulating layer VIA1. The connection electrode CNE, the first driving voltage supply line DSL1, and the second driving voltage supply line DSL2 may be substantially simultaneously formed. In an embodiment, a first conductive layer may be formed on the first via-insulating layer VIA1, and the first conductive layer may be patterned through a photolithography process and an etching process to form the connection electrode CNE, the first driving voltage supply line DSL1, and the second driving voltage supply line DSL2.

The second via insulation layer VIA2 may be formed on the connection electrode CNE, the first driving voltage supply line DSL1, and the second driving voltage supply line DSL2. The second via insulation layer VIA2 may be partially removed to form a contact hole exposing a portion of the connection electrode CNE, the first contact hole CNT1 exposing a portion of the first driving voltage supply line DSL1, and the second contact hole CNT2 exposing a portion of the second driving voltage supply line DSL2.

The pixel electrode PE and the bridge electrode BRE may be formed on the second via-insulating layer VIA2. The pixel electrode PE may be formed in the display area DA on the second via-insulating layer VIA2, and the bridge electrode BRE may be formed in the non-display area NDA on the second via-insulating layer VIA2. The bridge electrode BRE may be formed to overlap the demultiplexer circuit DMC in a plan view. The bridge electrode BRE may electrically connect the first driving voltage supply line DSL1 and the second driving voltage supply line DSL2. The first end portion of the bridge electrode BRE may be connected to the first driving voltage supply line DSL1 through the first contact hole CNT1, and the second end portion of the bridge electrode BRE may be connected to the second driving voltage supply line DSL2 through the second contact hole CNT2.

The central portion of the bridge electrode BRE located between the first end portion and the second end portion may define the plurality of holes H for outgassing in the first and second via-insulating layers VIA1 and VIA2. In a plan view, the holes H may be located between the first driving voltage supply line DSL1 and the second driving voltage supply line DSL2, and may be spaced apart from each other.

The pixel electrode PE and the bridge electrode BRE may be substantially simultaneously formed. In an embodiment, a second conductive layer may be formed on the second via-insulating layer VIA2, and the second conductive layer may be patterned through a photolithography process and an etching process to form the pixel electrode PE and the bridge electrode BRE which defines the plurality of holes H.

Referring to FIGS. 11 and 12, the organic insulating layer OIL may be formed on the second via-insulating layer VIA2, the pixel electrode PE, and the bridge electrode BRE.

A preliminary organic insulating layer OIL-p may be formed on the second via-insulating layer VIA2, the pixel electrode PE, and the bridge electrode BRE by applying a photoresist. In an embodiment, the preliminary organic insulating layer OIL-p may have the first thickness TH1. In an embodiment, the preliminary organic insulating layer OIL-p may include a positive photoresist.

The preliminary organic insulating layer OIL-p may be patterned through an exposure process and a development process using a mask MSK to form the organic insulating layer OIL including the first layer OIL1 and the second layer OIL2.

The mask MSK may be a halftone mask. The mask MSK may include light blocking portions LBP, light transmitting portions TP, and light semi-transmitting portions HTP. The light blocking portions LBP may be areas that blocks incident light incident on the mask MSK. The light transmitting portions TP and the light semi-transmitting portions HTP may be areas that transmit the incident light, and a light transmittance of the light semi-transmitting portions HTP may be less than a light transmittance of the light transmitting portions TP. For example, the light transmitting portions TP may transmit all of the incident light, and the light semi-transmitting portions HTP may transmit only a portion of the incident light.

Portions of the preliminary organic insulating layer OIL-p corresponding to the light blocking portions LBP may not be exposed to the incident light. Portions of the preliminary organic insulating layer OIL-p corresponding to the light transmitting portions TP may be exposed to the entirety of the incident light. Portions of the preliminary organic insulating layer OIL-p corresponding to the light semi-transmitting portions HTP may be exposed to a portion of the incident light.

When the preliminary organic insulating layer OIL-p is developed in the development process, the portions of the preliminary organic insulating layer OIL-p corresponding to the light blocking portions LBP may entirely remain, the portions of the preliminary organic insulating layer OIL-p corresponding to the light transmitting portions TP may be entirely removed, and the portions of the preliminary organic insulating layer OIL-p corresponding to the light semi-transmitting portions HTP may partially remain. Accordingly, as illustrated in FIG. 12, the organic insulating layer OIL including portions having the first thickness TH1, which is relatively thick, (i.e., including the first layer OIL1 and the second layer OIL2) and portions having the second thickness TH2, which is relatively thin, (i.e., including only the first layer OIL1) may be formed. That is, the organic insulating layer OIL may be formed as a single layer structure in which the first layer OIL1 and the second layer OIL2 are integrally formed through a single exposure process.

Referring to FIG. 13, the emission layer EL may be formed on the organic insulating layer OIL. The emission layer EL may be formed in the display area DA. For example, the emission layer EL may be formed through a deposition process using a deposition mask, and may also be formed a portion of the non-display area NDA such that an edge is located on the bridge electrode BRE, in consideration of a process margin. The common electrode CE may be formed on the organic insulating layer OIL and the emission layer EL.

According to embodiments, since the organic insulating layer OIL under the emission layer EL is formed to entirely have a thickness (i.e., to include the first layer OIL1 and the second layer OIL), which is relatively thick, in the area which overlaps the emission layer EL, the loss of the portion of the organic insulating layer OIL, which is between the bridge electrode BRE to which the driving voltage is applied and the emission layer EL, may be prevented or reduced. Accordingly, it is possible to prevent or reduce the abnormal light emission in which the emission layer EL emits light on the bridge electrode BRE in the non-display area NDA, thereby improving the reliability of the display device DD may be effectively improved.

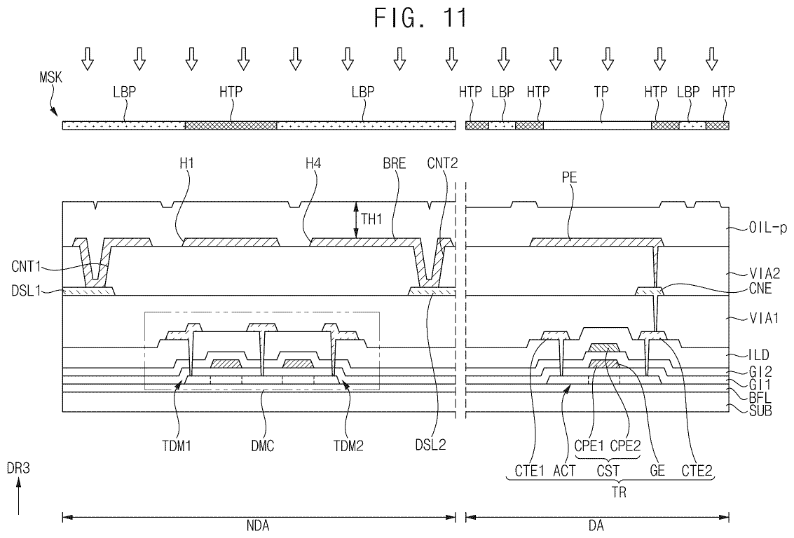

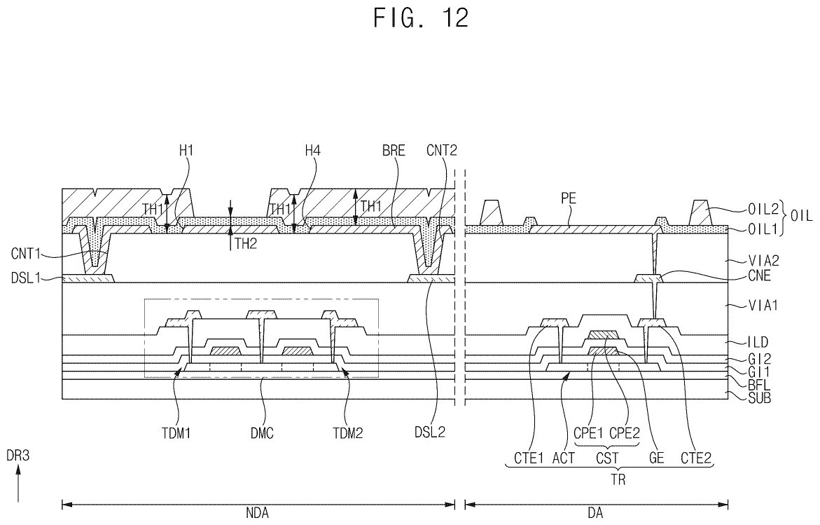

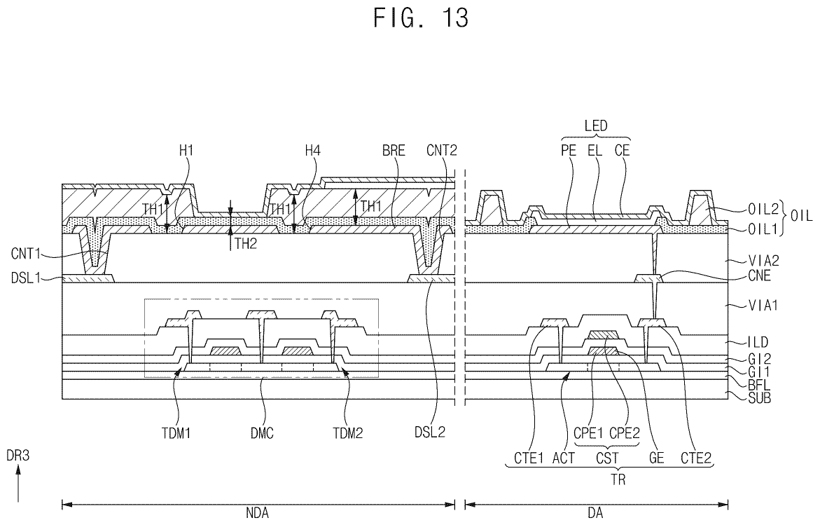

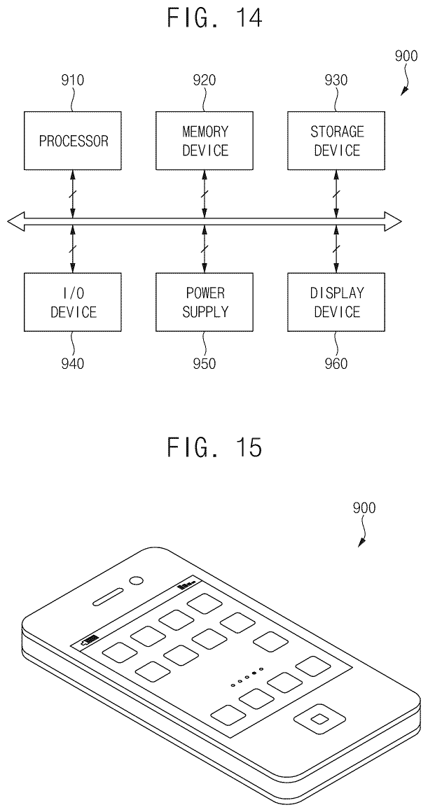

FIG. 14 is a block diagram illustrating an electronic device according to an embodiment.

Referring to FIG. 14, in an embodiment, an electronic device 900 may include a processor 910, a memory device 920, a storage device 930, an input/output (“I/O”) device 940, a power supply 950, and a display device 960. Here, the display device 960 may correspond the display device DD described above. The electronic device 900 may further include a plurality of ports for communicating with a video card, a sound card, a memory card, a universal serial bus (“USB”) device, or the like.

The processor 910 may perform various computing functions or tasks. In an embodiment, the processor 910 may be a microprocessor, a central processing unit (“CPU”), an application processor (“AP”), or the like. The processor 910 may be coupled to other components via an address bus, a control bus, a data bus, or the like. In an embodiment, the processor 910 may be coupled to an extended bus such as a peripheral component interconnection (“PCI”) bus.

The memory device 920 may store data for operations of the electronic device 900. In an embodiment, the memory device 920 may include at least one non-volatile memory device such as an erasable programmable read-only memory (“EPROM”) device, an electrically erasable programmable read-only memory (“EEPROM”) device, a flash memory device, a phase change random access memory (“PRAM”) device, a resistance random access memory (“RRAM”) device, a nano floating gate memory (“NFGM”) device, a polymer random access memory (“PoRAM”) device, a magnetic random access memory (“MRAM”) device, a ferroelectric random access memory (“FRAM”) device, or the like, and/or at least one volatile memory device such as a dynamic random access memory (“DRAM”) device, a static random access memory (“SRAM”) device, a mobile DRAM device, or the like.

In an embodiment, the storage device 930 may include a solid state drive (“SSD”) device, a hard disk drive (“HDD”) device, a CD-ROM device, or the like. In an embodiment, the I/O device 940 may include an input device such as a keyboard, a keypad, a mouse device, a touchpad, a touch-screen, or the like, and an output device such as a printer, a speaker, or the like.

The power supply 950 may provide power for operations of the electronic device 900. The display device 960 may be coupled to other components via the buses or other communication links. In an embodiment, the display device 960 may be included in the I/O device 940.

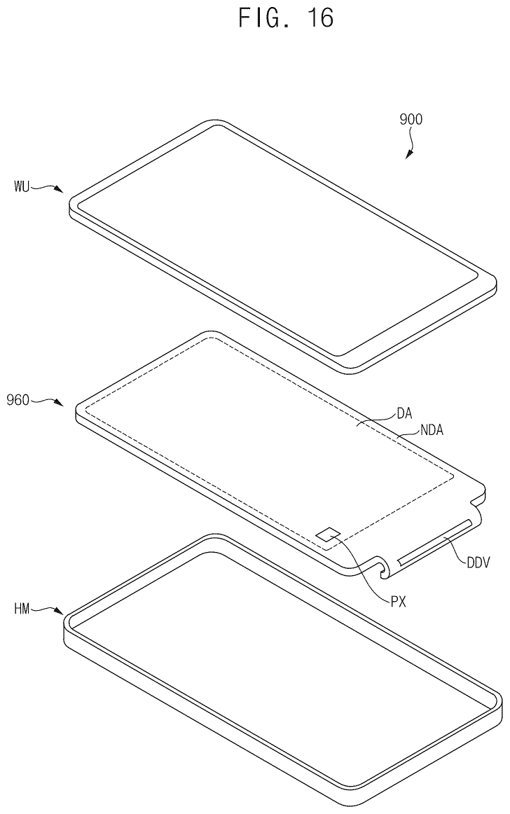

FIG. 15 is a view illustrating an example in which the electronic device of FIG. 14 is implemented as a smartphone. FIG. 16 is an exploded perspective view of the electronic device of FIG. 15.

Referring to FIG. 15, in an embodiment, the electronic device 900 may be implemented as a smartphone. However, the electronic device 900 may not be limited thereto, and for example, the electronic device 900 may be implemented as a television, a mobile phone, a video phone, a smart pad, a smart watch, a tablet PC, a vehicle navigation, a computer monitor, a notebook computer, a head mounted display (“HMD”), a kiosk, or the like. Hereinafter, an embodiment in which the electronic device 900 is implemented as a smartphone will be described in more detail with reference to FIGS. 15 and 16.

Referring to FIGS. 15 and 16, in an embodiment, the electronic device 900 may include a window WU, a display device 960, and a housing HM. The window WU and the housing HM may be coupled to define the external appearance of the electronic device 900.

The display device 960 may display an image. The display device 960 may include the display area DA displaying the image and the non-display area NDA located around the display area DA. The plurality of pixels PX for generating the image may be disposed in the display area DA. A driver (e.g., a data driver DDV) for driving the pixels PX may be disposed in the non-display area NDA. The display device 960 may correspond to one of the display device DD described above.

The window WU may define a front surface of the electronic device 900. The window WU may have light-transmitting properties. For example, the window WU may include a resin film such as polyimide or ultra-thin glass.

The housing HM may be coupled with the window WU. The housing HM may be coupled with the window WU to provide an internal space. The display device 960 may be accommodated in the internal space provided between the housing HM and the window WU. Various components, such as an optical film, a cushion layer, a heating layer, the processor, the memory device, the storage device, the I/O device, the power supply, or the like may be further accommodated in the internal space. The housing HM can include a material having relatively high rigidity. The housing HM can stably protect the components accommodated in the internal space from external impact.

Although embodiments and implementations have been described herein, other embodiments and modifications will be apparent from this description. Accordingly, the invention is not limited to such embodiments, but rather to the broader scope of the appended claims and various obvious modifications and equivalent arrangements as would be apparent to a person of ordinary skill in the art.

What is claimed is:

1. A display device comprising:
a substrate including a display area and a non-display area;
a first driving voltage supply line disposed in the non-display area, extending in a first direction, and to which a driving voltage is applied;
a second driving voltage supply line disposed between the display area and the first driving voltage supply line in a plan view, extending in the first direction, and spaced apart from the first driving voltage supply line;
a bridge electrode disposed on the first driving voltage supply line and the second driving voltage supply line, and electrically connecting the first driving voltage supply line and the second driving voltage supply line to each other;
an organic insulating layer disposed on the bridge electrode, and including a first portion adjacent to the first driving voltage supply line and a second portion adjacent to the second driving voltage supply line; and
an emission layer disposed in the display area and extending from the display area to the non-display area such that one end portion of the emission layer in the non-display area overlaps the bridge electrode in the plan view,
wherein an average thickness of the first portion of the organic insulating layer is less than an average thickness of the second portion of the organic insulating layer.

2. The display device of claim 1, wherein in the plan view,
the first portion of the organic insulating layer overlaps the bridge electrode and doesn't overlap the emission layer, and
the second portion of the organic insulating layer overlaps both the bridge electrode and the emission layer.

3. The display device of claim 1, wherein a thickness deviation in the first portion of the organic insulating layer is greater than a thickness deviation in the second portion of the organic insulating layer.

4. The display device of claim 1, wherein in the plan view,
the second driving voltage supply line is spaced apart from the display area in a second direction crossing the first direction, and
the first driving voltage supply line is spaced apart from the second driving voltage supply line in the second direction.

5. The display device of claim 4, wherein the first portion of the organic insulating layer is located in the second direction from the second portion of the organic insulating layer.

6. The display device of claim 1, wherein the bridge electrode defines a plurality of holes located between the first driving voltage supply line and the second driving voltage supply line and spaced apart from each other in the plan view.

7. The display device of claim 6, wherein
the plurality of holes include first holes adjacent to the first driving voltage supply line, arranged along the first direction, and spaced apart from the emission layer in the plan view,
a first-first portion in the first portion of the organic insulating layer, overlapping the first holes in the plan view, has a first thickness, and
a first-second portion in the first portion of the organic insulating layer, overlapping a first portion of the bridge electrode between the first holes in the first direction in the plan view, has a second thickness less than the first thickness.

8. The display device of claim 7, wherein
the plurality of holes include second holes adjacent to the second driving voltage supply line, arranged along the first direction, and overlapping the emission layer in the plan view,
a second-first portion in the second portion of the organic insulating layer, overlapping the second holes in the plan view, has the first thickness, and
a second-second portion in the second portion of the organic insulating layer, overlapping a second portion of the bridge electrode between the second holes in the first direction in the plan view, has the first thickness.

9. The display device of claim 1, further comprising:
a demultiplexer circuit disposed between the substrate and the bridge electrode and overlapping the bridge electrode in the plan view.

10. The display device of claim 1, further comprising:
a pixel electrode disposed in the display area, and
wherein the bridge electrode includes a same material as the pixel electrode.

11. A method of manufacturing a display device, the method comprising:
forming a first driving voltage supply line and a second driving voltage supply line in a non-display area on a substrate including a display area and the non-display area, wherein the first driving voltage supply line extends in a first direction, a driving voltage is applied to the first driving voltage supply line, and the second driving voltage supply line is disposed between the display area and the first driving voltage supply line in a plan view, extends in the first direction, and is spaced apart from the first driving voltage supply line;
forming a bridge electrode on the first driving voltage supply line and the second driving voltage supply line, wherein the bridge electrode electrically connects the first driving voltage supply line and the second driving voltage supply line;
forming a preliminary organic insulating layer on the bridge electrode;
patterning the preliminary organic insulating layer using a mask to form an organic insulating layer including a first portion adjacent to the first driving voltage supply line and a second portion adjacent to the second driving voltage supply line; and
forming an emission layer extending from the display area to the non-display area such that one end portion of the emission layer in the non-display area overlaps the bridge electrode in the plan view, and
wherein an average thickness of the first portion of the organic insulating layer is less than an average thickness of the second portion of the organic insulating layer.

12. The method of claim 11, wherein in the plan view,
the first portion of the organic insulating layer overlaps the bridge electrode and doesn't overlap the emission layer, and
the second portion of the organic insulating layer overlaps both the bridge electrode and the emission layer.

13. The method of claim 11, wherein a thickness deviation in the first portion of the organic insulating layer is greater than a thickness deviation in the second portion of the organic insulating layer.

14. The method of claim 11, wherein the mask is a halftone mask.

15. The method of claim 11, wherein the bridge electrode defines a plurality of holes located between the first driving voltage supply line and the second driving voltage supply line and spaced apart from each other in the plan view.

16. The method of claim 15, wherein
the plurality of holes include first holes adjacent to the first driving voltage supply line, arranged along the first direction, and spaced apart from the emission layer in the plan view,
a first-first portion in the first portion of the organic insulating layer, overlapping the first holes in the plan view, has a first thickness, and
a first-second portion in the first portion of the organic insulating layer, overlapping a first portion of the bridge electrode between the first holes in the first direction in the plan view, has a second thickness less than the first thickness.

17. The method of claim 16, wherein
the plurality of holes include second holes adjacent to the second driving voltage supply line, arranged along the first direction, and overlapping the emission layer in the plan view,
a second-first portion in the second portion of the organic insulating layer, overlapping the second holes in the plan view, has the first thickness, and
a second-second portion in the second portion of the organic insulating layer, overlapping a second portion of the bridge electrode between the second holes in the first direction in the plan view, has the first thickness.

18. The method of claim 11, further comprising:
before the forming of the first driving voltage supply line and the second driving voltage supply line, forming a pixel circuit in the display area and a demultiplexer circuit in the non-display area, and
wherein the bridge electrode overlaps the demultiplexer circuit in the plan view.

19. The method of claim 11, wherein the forming of the bridge electrode includes:
forming a conductive layer on the display area and the non-display area; and
patterning the conductive layer to form a pixel electrode in the display area and the bridge electrode in the non-display area.

20. An electronic device comprising:
a window;
a housing coupled with the window to provide an internal space; and
a display device accommodated in the internal space between the housing and the window, the display device including:
a substrate including a display area and a non-display area;
a first driving voltage supply line disposed in the non-display area, extending in a first direction, and to which a driving voltage is applied;
a second driving voltage supply line disposed between the display area and the first driving voltage supply line in a plan view, extending in the first direction, and spaced apart from the first driving voltage supply line;
a bridge electrode disposed on the first driving voltage supply line and the second driving voltage supply line, and electrically connecting the first driving voltage supply line and the second driving voltage supply line to each other;
an organic insulating layer disposed on the bridge electrode, and including a first portion adjacent to the first driving voltage supply line and a second portion adjacent to the second driving voltage supply line; and
an emission layer disposed in the display area and extending from the display area to the non-display area such that one end portion of the emission layer in the non-display area overlaps the bridge electrode in the plan view, and
wherein an average thickness of the first portion of the organic insulating layer is less than an average thickness of the second portion of the organic insulating layer.
